(19) United States
(12) Patent Application Publication
(10) Pub. No.: US 2009/0239341 A1
(43) Pub. Date: Sep. 24, 2009

(54) IC PACKAGING PROCESS

(75) Inventor: Chung-Mao YEH, Taichung City (TW)

Correspondence Address: BROWDY AND NEIMARK, P.L.L.C.;624 NINTH STREET, NW, SUITE 300, WASHINGTON, DC, 20001-5303, US

(73) Assignee: LINGSEN PRECISION INDUSTRIES, LTD., Taichung (TW)

(21) Appl. No.: 12/264,411

(22) Filed: Nov. 4, 2008

(30) Foreign Application Priority Data
Mar. 18, 2008 (TW) 97109545

(51) Int. Cl. H01L 21/50

(52) U.S. Cl. 438/118; 257/E21.499

(57) ABSTRACT

An IC packaging process includes the steps of preparing a substrate having a chip-receiving place formed on a front side thereof; creating a dam layer on the front side of the substrate; coating an ultraviolet adhesive layer on the dam layer; removing a part of the ultraviolet adhesive layer that corresponds to the chip-receiving place; removing a part of the dam layer that corresponds to the chip-receiving place; mounting a chip to the chip-receiving place in the open chamber and bonding wires between the substrate and the chip for electrical connection of the chip and the substrate; and mounting a cover layer on the ultraviolet adhesive layer and then heating the ultraviolet adhesive layer to adhesively fasten the cover layer on the dam layer. Accordingly, the IC packaging process effectively reduces the adhesive squeeze-out to prevent it from damage to the chip.

### BACKGROUND OF THE INVENTION

1. Field of the Invention

The present invention relates generally to IC package, and more particularly, to an IC packaging process.

2. Description of the Related Art

The conventional IC packaging process of a semiconductor element, like micro electromechanical system (MEMS) chip or complementary metal oxide semiconductor (CMOS) chip, includes the steps of adhering a chip to chip-receiving place of a substrate; creating a wall-like dam around the chip, the bottom side of the dam being connected with the periphery of the chip-receiving place, the chip being surrounded by the dam; electrically connecting the chip with the substrate; and finally disposing adhesive on the upper surface of the dam and mounting a sealing cover, like glass, onto the dam to package the chip inside a closed chamber.

However, in such conventional IC packaging process, the adhesive is colloid to have unstable physical property, such that it is not easy to evenly dispose the adhesive on the upper surface of the dam. After the sealing cover is mounted on the dam, the adhesive is subject to squeeze-out to stain the chip. Further, when the sealing cover is adhered to the dam, the sealing cover is subject to shaking because of the unset adhesive, such that the sealing is defective. Therefore, further improvement is necessary.

### SUMMARY OF THE INVENTION

The primary objective of the present invention is to provide an IC packaging process, which can effectively reduce the adhesive squeeze-out to prevent it from damage to the chip.

The foregoing objective of the present invention is attained by the IC packaging process including the steps of preparing a substrate having a chip-receiving place formed on a front side thereof; creating a dam layer on the front side of the substrate, the dam layer being a square block and having a lower surface fully covering the chip-receiving place; coating an ultraviolet adhesive layer on the dam layer; removing a part of the ultraviolet adhesive layer that corresponds to the chip-receiving place; removing a part of the dam layer that corresponds to the chip-receiving place to enable the ultraviolet adhesive layer to be formed on the dam layer, whereby an open chamber is formed and surrounded by both the ultraviolet adhesive layer and the dam layer; mounting a chip to the chip-receiving place in the open chamber and bonding wires between the substrate and the chip for electrical connection of the chip and the substrate; and mounting a cover layer on the ultraviolet adhesive layer to seal the open chamber and then heating the ultraviolet adhesive layer to adhesively fasten the cover layer on the dam layer.

### BRIEF DESCRIPTION OF THE DRAWINGS

FIG. 1 is a flow chart of a preferred embodiment of the present invention.

FIG. 2(A) illustrates the first step of the preferred embodiment of the present invention.

FIG. 2(B) illustrates the second step of the preferred embodiment of the present invention.

FIG. 2(C) illustrates the third step of the preferred embodiment of the present invention.

FIG. 2(D) illustrates the fourth step of the preferred embodiment of the present invention.

FIG. 2(E) illustrates the fifth step of the preferred embodiment of the present invention.

FIG. 2(G) illustrates the sixth step of the preferred embodiment of the present invention.

### DETAILED DESCRIPTION OF PREFERRED EMBODIMENTS

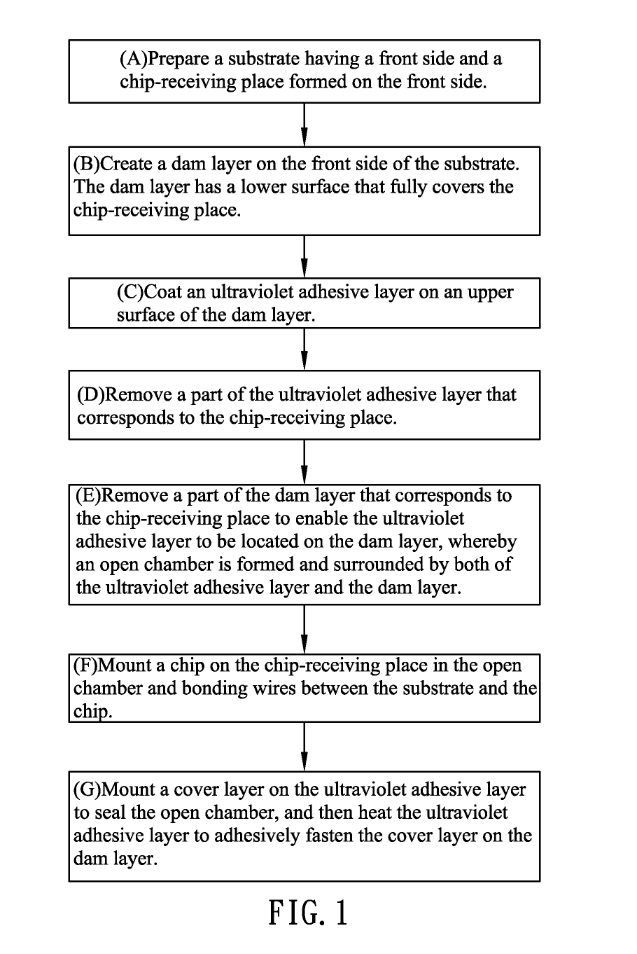

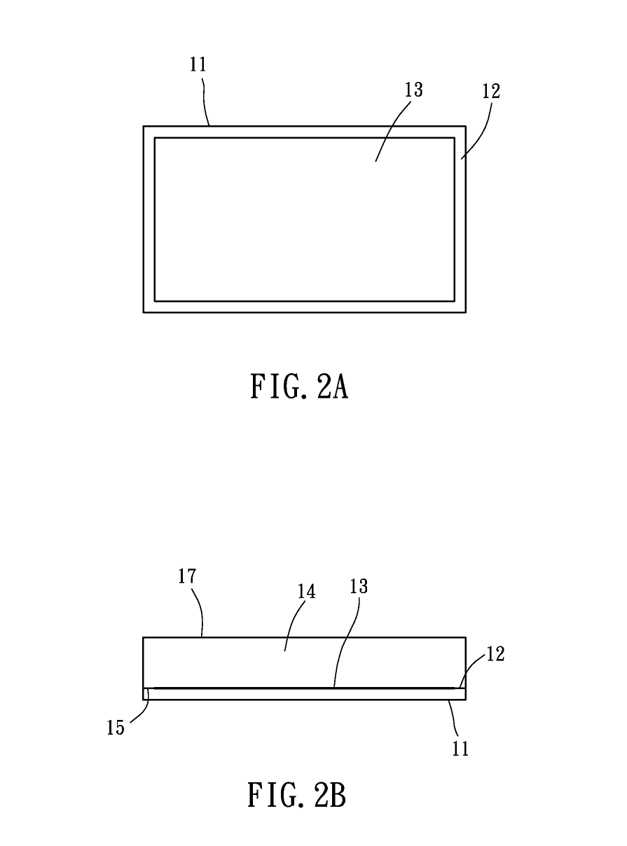

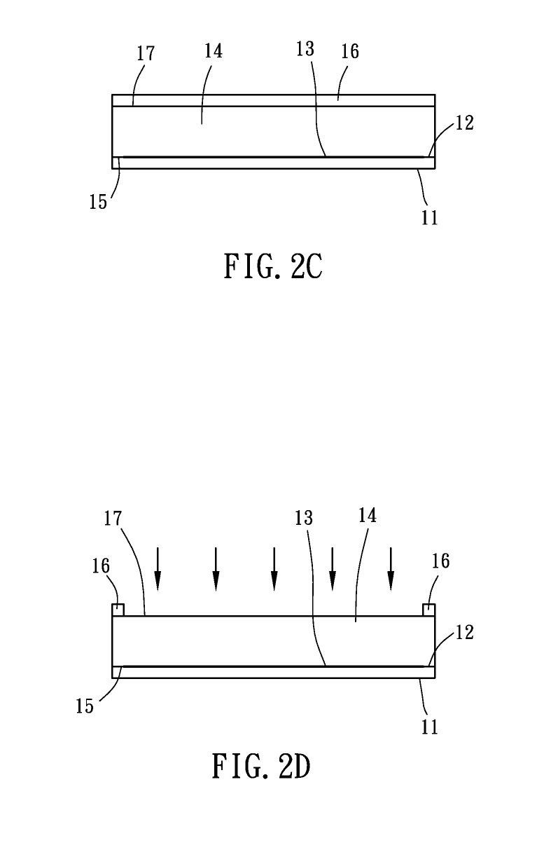

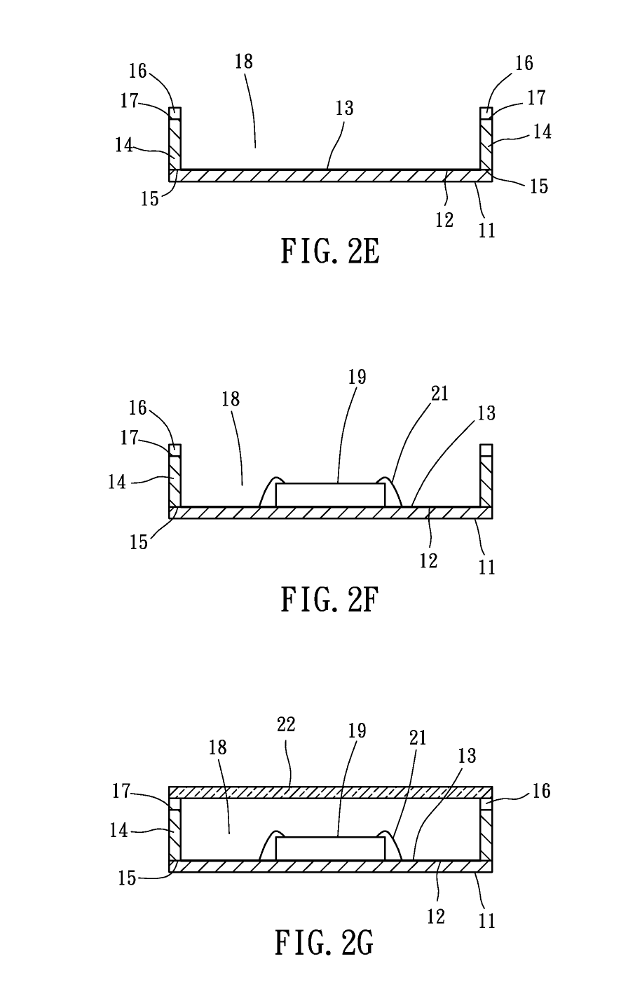

Referring to FIG. 1 and FIGS. 2(A)-2(G), an IC packaging process in accordance with a preferred embodiment of the present invention includes the following steps.

(A) Prepare a substrate 11 having a front side 12 and a chip-receiving place 13 formed on the front side 12.

(B) Create a dam layer 14 on the front side 12 of the substrate 11. The dam layer 14 is a square block, having a lower surface 15 that fully covers the chip-receiving place 13.

(C) Coat an ultraviolet adhesive layer 16 of a predetermined thickness on an upper surface 17 of the dam layer 14. The ultraviolet adhesive layer 16 is fully disposed on the upper surface 17 of the dam layer 14 and then solidified after a while.

(D) Remove a part of the ultraviolet adhesive layer 16 that corresponds to the chip-receiving place 13. The other part of the ultraviolet adhesive layer 16 for reservation is shielded by a cover beforehand, the part of the ultraviolet adhesive layer 16 that is not shielded is etched by photolithography, and then the part of the ultraviolet adhesive layer that corresponds to the chip-receiving place 13 is removed, and finally the cover is removed.

(E) Remove a part of the dam layer 14 that corresponds to the chip-receiving place 13. Because the part of the ultraviolet adhesive layer 16 that corresponds to the chip-receiving place 13 is removed, the dam layer 16 located beneath the ultraviolet adhesive layer 16 is exposed and what corresponds to the chip-receiving place 13 for the dam layer 16 is then removed by abrasion, etching, or drilling. Further, what is removed in the ultraviolet adhesive layer 16 and what is removed in the dam layer 14 each correspond to the chip-receiving place 13, such that an open chamber 18 is formed and surrounded by both the remaining ultraviolet adhesive layer 16 and dam layer 14, whose bottom side is the chip-receiving place 13.

(F) Mount a chip 19 on the chip-receiving place 13 in the open chamber 18 and bond wires between the chip 19 and the substrate 11 for electrical connection of the chip 19 and the substrate 11.

(G) Mount a cover layer 22 on the open chamber 18 and heat the ultraviolet adhesive layer 16 to adhesively fasten the cover layer 22 on the ultraviolet adhesive layer 16. In this way, the cover layer 22 seals the open chamber 18 to seal the chip 19 in the open chamber 18. Because the open chamber 18 is defined by the ultraviolet adhesive layer 16 and the dam layer 14 and the ultraviolet adhesive layer 16 is located on the dam layer 14, the cover layer 22 is closely in contact with the ultraviolet adhesive layer 16. After the heating, the cover layer 22 is adhesively connected with the ultraviolet adhesive layer 16.

In addition, the ultraviolet adhesive layer 16 is made of B-Stage epoxy and the cover layer 22 is made of glass in this embodiment.

In conclusion, the present invention greatly reduces the adhesive squeeze-out during the IC packaging process and simplifies the IC packaging steps to smooth the IC packaging process. Besides, the present invention does not need extra technology, such that no more cost will be incurred for the production that the present invention is applied to.

Although the present invention has been described with respect to a specific preferred embodiment thereof, it is no way limited to the details of the illustrated structures but changes and modifications may be made within the scope of the appended claims.

What is claimed is:

1. An IC packaging process comprising steps of:
(A) preparing a substrate, said substrate having a front side and a chip-receiving place formed on said front side;
(B) creating a dam layer on said front side of said substrate, said dam layer having a lower surface fully covering said chip-receiving place;
(C) coating an ultraviolet adhesive layer on an upper surface of said dam layer;
(D) photolithographing said ultraviolet adhesive layer and then removing a part of said ultraviolet adhesive layer that corresponds to said chip-receiving place after said ultraviolet adhesive layer is solidified;
(E) removing a part of said dam layer that corresponds to said chip-receiving place to enable said ultraviolet adhesive layer to be located on said dam layer, whereby an open chamber is formed and surrounded by both said ultraviolet adhesive layer and said dam layer;
(F) mounting a chip on said chip-receiving place in said open chamber and bonding wires between said substrate and said chip; and
(G) mounting a cover layer on said ultraviolet adhesive layer to seal said open chamber, and then heating said ultraviolet adhesive layer to adhesively fasten said cover layer on said dam layer.

2. The IC packaging process as defined in claim 1, the part of said dam layer that corresponds to said chip-receiving place in the step (E) is removed by abrasion.

3. The IC packaging process as defined in claim 1, wherein said ultraviolet adhesive layer is B-Stage epoxy.
